(19) United States
(12) Patent Application Publication
(10) Pub. No.: US 2013/0075801 A1
(43) Pub. Date: Mar. 28, 2013

(54) SELF-ADJUSTED CAPACITIVE STRUCTURE

(71) Applicants: Hans Weber, Bayerisch Gmain (DE); Roman Knoefler, Villach (AT); Kurt Sorschag, Villach (AT)

(72) Inventors: Hans Weber, Bayerisch Gmain (DE); Roman Knoefler, Villach (AT); Kurt Sorschag, Villach (AT)

(73) Assignee: Infineon Technologies Austria AG, Villach (AT)

(21) Appl. No.: 13/242,842

(22) Filed: Sep. 23, 2011

(51) Int. Cl. H01L 29/94; H01L 29/92; H01L 21/02

(52) U.S. Cl. 257/302; 438/386; 257/532; 257/E21.008; 257/E29.342; 257/E29.345

(57) ABSTRACT

A method for producing a capacitive structure in a semiconductor body includes forming a first trench in a first surface of the semiconductor body, forming a first dielectric layer on sidewalls and the bottom of the first trench, forming a first electrode layer on the first dielectric layer, forming at least one second trench by removing at least one part of the first dielectric layer to form a first gap in the first surface, and by widening the first gap, forming a second dielectric layer on sidewalls and the bottom of the at least one second trench, and forming a second electrode layer on the second dielectric layer.

### TECHNICAL FIELD

Embodiments of the present invention relate to a method for producing a capacitive structure in a semiconductor body.

### BACKGROUND

A capacitive structure integrated in a semiconductor body may be used as a capacitor for storing electrical charge, but may also be used as a gate structure of an MOS transistor, such as a MOSFET or an IGBT. With an increasing density of semiconductor devices implemented in a semiconductor body the area available for one device or for one device structure decreases. When the area available for one device or for one device structure decreases, manufacturing processes need to become more precise, specifically concerning the positioning of the device in the semiconductor body.

There is therefore a need to provide a method for producing a capacitive structure in a semiconductor body, that allows for a further increase of the device density.

### SUMMARY

A first embodiment relates to a method for producing a capacitive structure in a semiconductor body. The method includes forming a first trench in a first surface of the semiconductor body, forming a first dielectric layer on sidewalls and the bottom of the first trench, and forming a first electrode layer on the first dielectric layer. The method further includes forming at least one second trench by removing at least one part of the first dielectric layer to form a first gap in the first surface, and by widening the first gap, forming a second dielectric layer on sidewalls and the bottom of the at least one second trench, and forming a second electrode layer on the second dielectric layer.

A second embodiment relates to a method for forming a multi-level capacitive structure. The method includes forming a 1st level capacitive structure in a semiconductor body, the 1st level capacitive structure comprising a first trench, a first dielectric layer on sidewalls and a bottom of the first trench and a first electrode layer arranged on the first dielectric layer. The method further includes forming at least one 2nd level capacitive structure in the semiconductor body, the at least one 2nd level capacitive comprising a second trench adjusted to one sidewall of the former first trench, a first dielectric layer on sidewalls and a bottom of the second trench and a second electrode layer arranged on the second dielectric layer.

A third embodiment relates to a multi-level capacitive structure including a 1st level capacitive structure in a semiconductor body and at least one 2nd level capacitive structure in the semiconductor body. The 1st level capacitive structure includes a first trench, a first dielectric layer on sidewalls and a bottom of the first trench and a first electrode layer arranged on the first dielectric layer. The at least one 2nd level capacitive structure includes a second trench adjusted to one sidewall of the first trench, a first dielectric layer on sidewalls and a bottom of the second trench and a second electrode layer arranged on the second dielectric layer.

A fourth embodiment relates to a transistor device, including: a drain region, a source region, a body region and a drift region arranged in a semiconductor body, the body region arranged between the source region and the drift region, and the drift region arranged between the body region and the drain region; a gate structure including a gate electrode arranged adjacent to the body region, and a gate dielectric arranged between the gate electrode and the body region; a drift control region arranged adjacent to the drift region in a lateral direction of the semiconductor body, and a drift control region dielectric arranged between the drift control region and the drift region and extending in a vertical direction of the semiconductor body; and a capacitive element electrically coupled to the drift control region. The transistor device further includes a multi-level capacitive structure in the semiconductor body that is self-adjusted to the drift control region dielectric and that is part of at least one of the gate structure and the capacitive element.

Those skilled in the art will recognize additional features and advantages upon reading the following detailed description, and upon viewing the accompanying drawings.

### BRIEF DESCRIPTION OF THE DRAWINGS

Examples will now be explained with reference to the drawings. The drawings serve to illustrate the basic principle, so that only aspects necessary for understanding the basic principle are illustrated. The drawings are not to scale. In the drawings the same reference characters denote like features.

FIG. 1 which includes FIGS. 1A to 1G illustrates a first embodiment of a method for producing a multi-level capacitive structure in a semiconductor body.

FIG. 2 which includes FIGS. 2A and 2C illustrates horizontal cross sectional views of the semiconductor body after producing a first trench in the semiconductor body.

FIG. 3 illustrates a vertical cross sectional view of a capacitive structure integrated in a semiconductor body obtained through the method illustrated in FIGS. 1A to 1G with modifications.

FIG. 4 illustrates a vertical cross sectional view of a 3-level capacitive structure integrated in a semiconductor body.

FIG. 5 illustrates a vertical cross sectional view of a 3-level capacitive structure according to a further embodiment integrated in a semiconductor body.

FIG. 6 which includes FIGS. 6A and 6D illustrates a further modification of the method of FIGS. 1A to 1G.

FIG. 7 which includes FIGS. 7A to 7D illustrates a further modification of the method illustrated in FIGS. 1A to 1G.

FIG. 8 illustrates a vertical cross sectional view of a 2-level capacitive structure.

FIG. 9 illustrates a vertical cross sectional view of a 3-level capacitive structure.

FIG. 10 illustrates a vertical cross sectional view of a 3-level capacitive structure according to a further embodiment.

FIG. 11 illustrates a vertical cross sectional view of a 3-level capacitive structure according to another embodiment.

FIG. 12 which includes FIGS. 12A to 12B illustrates a further method for producing a capacitive structure in a semiconductor body.

FIG. 13 illustrates a vertical cross sectional view of a MOSFET including a drift control region adjacent to a drift region.

FIG. 14 illustrates an embodiment of a MOSFET including a 2-level capacitive structure that forms a capacitive element.

FIG. 15 illustrates an embodiment of a MOSFET including a self-adjusted 1-level capacitive structure that forms a capacitive element.

FIG. 16 illustrates a modification of the MOSFET of FIG. 15.

FIG. 17 illustrates an embodiment of a MOSFET including a 2-level capacitive structure that forms a gate electrode and a capacitive element.

FIG. 18 illustrates an embodiment of a MOSFET including a 3-level capacitive structure that forms a gate electrode and a capacitive element.

FIG. 19 illustrates a further embodiment of a MOSFET a 3-level capacitive structure that forms a gate electrode and a capacitive element.

### DETAILED DESCRIPTION

In the following detailed description, reference is made to the accompanying drawings, which form a part thereof, and in which is shown by way of illustration specific embodiments in which the invention may be practiced. In this regard, directional terminology, such as “top”, “bottom”, “front”, “back”, “leading”, “trailing” etc., is used with reference to the orientation of the FIGs. being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

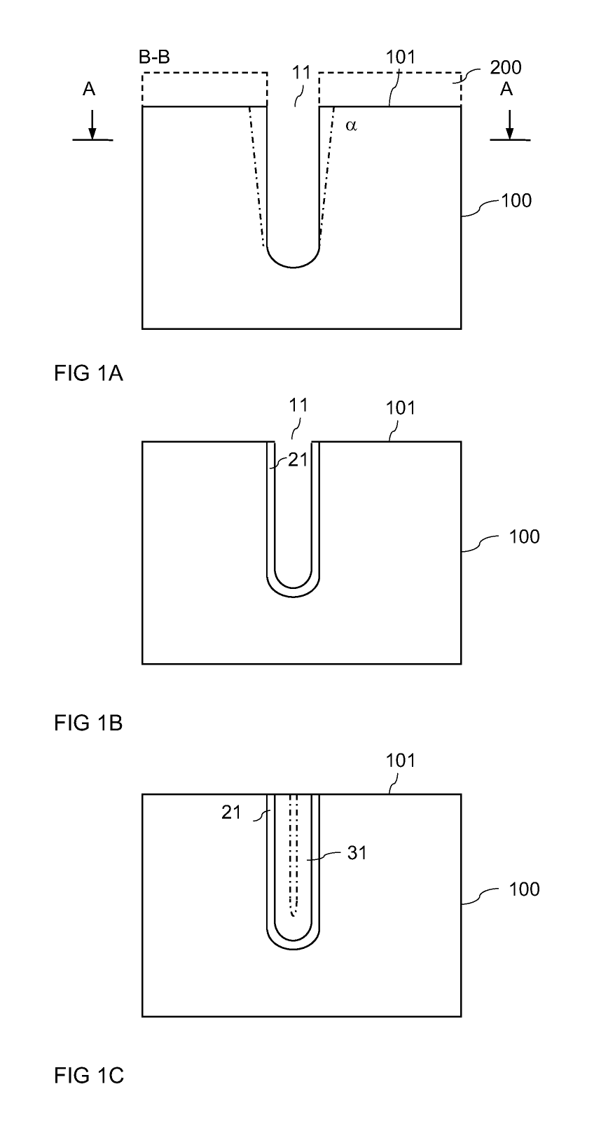

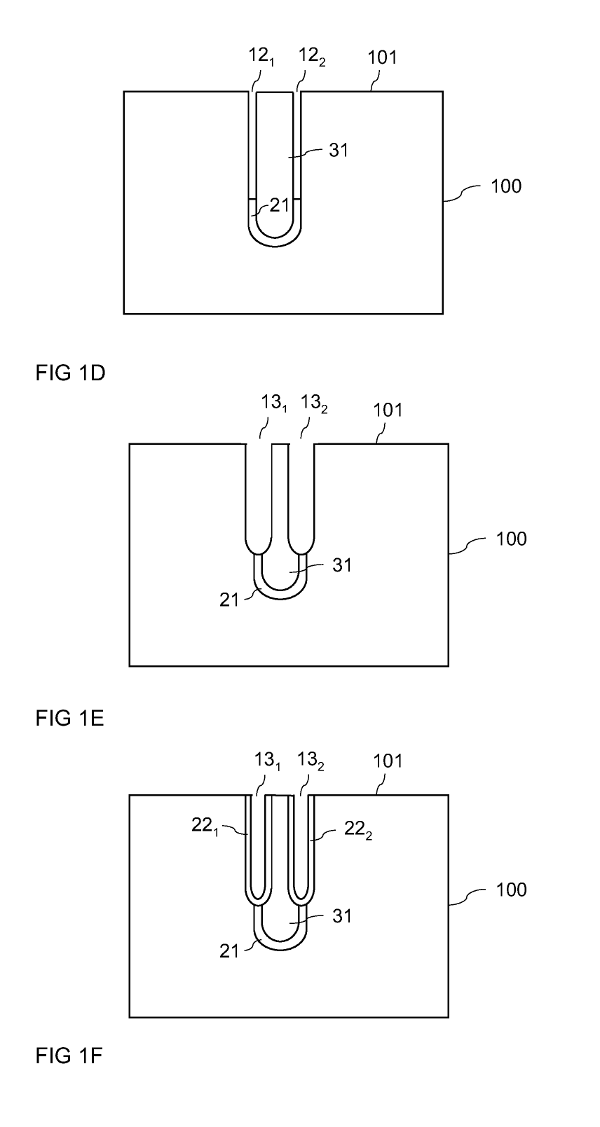

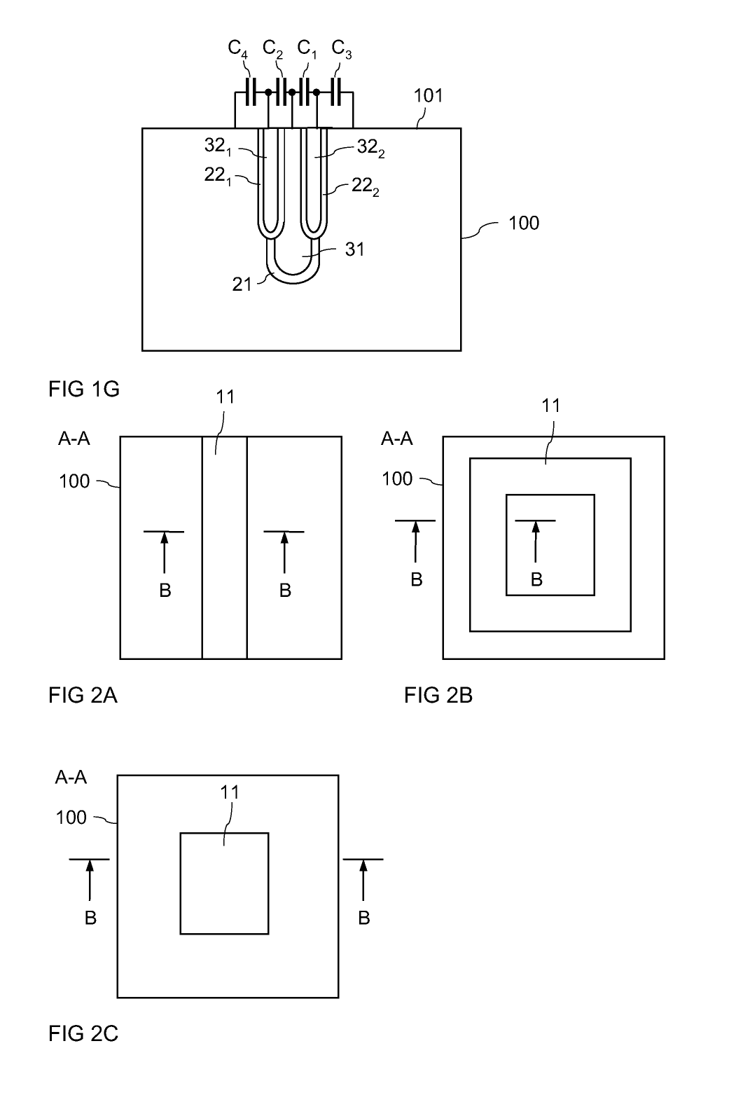

FIGS. 1A to 1G illustrate a first embodiment of a method for producing a capacitive structure in a semiconductor body 100, in particular for producing a multi-level capacitive structure. FIGS. 1A to 1G each show a vertical cross sectional view of the semiconductor body 100, which is a cross sectional view in a section plane perpendicular to a first surface 101 of the semiconductor body 100. In FIGS. 1A to 1G, as well as in the other figures explained below, only a section of the semiconductor body 100 is illustrated, namely that section in which the capacitive structure is implemented. A plurality of capacitive structures or other semiconductor devices can be implemented in the semiconductor body 100, even though only one capacitive structure is illustrated in the individual figures.

The semiconductor body 100 may include a conventional semiconductor material, such as silicon (Si), silicon carbide (SiC), gallium nitride (GaN), gallium arsenide (GaAs), or the like.

Referring to FIG. 1A, first method steps include forming a first trench 11 in the first surface 101 of the semiconductor body 100. Forming the first trench 11 may include an etching process, such as an anisotropic etching process, using an etch mask 200 (illustrated in dashed lines) formed on the first surface 101 of the semiconductor body 100. In FIG. 1A, the first trench 11 is illustrated to have vertical sidewalls and a rounded bottom. The specific geometry of the first trench 11, however, is dependent on the etching process, so that having a trench with vertical sidewalls and a rounded bottom is only one a plurality of different possibilities. According to a further embodiment (illustrated in dashed and dotted lines in FIG. 1A), the trench sidewalls are tapered, so that an angle □ between the sidewalls and the first surface 101 is different from 90°, such as between 90° and 110°, in particular between 90° and 100°. Just for illustration purposes it is assumed in the following that the trench sidewalls of the first trench 100 are vertical sidewalls. In a direction perpendicular to the section plane illustrated in FIG. 1A, the first trench 11 may have any desired form or geometry.

Referring to FIG. 2A which illustrates a horizontal cross sectional view of the semiconductor body 100, the first trench 11 may be a longitudinal (stripe-shaped) trench. According to a further embodiment illustrated in FIG. 2B, the trench 11 may have the form of a closed loop. In the embodiment illustrated in FIG. 2B, the closed loop has a rectangular geometry. However, this is only one of a plurality of different possibilities. According to further embodiments (not illustrated) the closed loop has an elliptical, a circular, a hexagonal, or any other polygonal geometry, or the like. According to a further embodiment illustrated in FIG. 1C, the trench 11 may be pile-shaped with a rectangular cross section (as illustrated), an elliptical cross section, a circular cross section, or the like.

Referring to FIG. 1B the method further includes forming a first dielectric layer 21 on the bottom and the sidewalls of the first trench 11. The dielectric layer 21 may include a conventional dielectric material, such as an oxide, a nitride, or a high-k-dielectric. The first dielectric layer 21 may include a homogenous dielectric layer of one dielectric material or of a composition of two or more dielectric materials, or may include a layer stack with several sub-layers of different dielectric materials. According to one embodiment, the dielectric layer 21 is formed on the first surface 101 and on the bottom and the sidewalls of the first trench 11 and is then removed from the first surface 101. When the first dielectric layer 21 is also formed on the first surface 101, this dielectric layer on the first surface 101 can be removed before next method steps illustrated in FIG. 1C or after these next method steps.

Referring to FIG. 1C, these next method steps include forming a first electrode layer 31 on the first dielectric layer 21 at least in the first trench 11. The first electrode layer 31 may completely fill the first trench 11 (as illustrated in FIG. 1C). According to a further embodiment, the first electrode layer 31 covers the first dielectric layer 21, but does not completely fill the first trench 11, so that a residual trench remains (as illustrated in dashed and dotted lines in FIG. 1C).

Forming the electrode layer 31 on the sidewalls and the bottom of the trench 11 may include forming the electrode layer 31 above the first surface 101 and on the sidewalls and the bottom of the first trench 11 and removing the electrode layer 31 from above the first surface. According to one embodiment, the dielectric layer 21 is still present on the first surface 101 when the electrode layer 31 is formed, so that on the first surface 101 the electrode layer 31 is also formed on the dielectric layer 21. The electrode layer 31 and the dielectric layer 21 are then removed from the first surface 101, so as to obtain the structure illustrated in FIG. 1C. Removing the electrode layer 31 and the dielectric layer 21 from the first surface 101 may include at least one of a polishing step, such as a mechanical polishing step, a chemical polishing step, or a chemical-mechanical polishing step (CMP), and an etching process. According to one embodiment, the electrode layer 31 is removed using a polishing or an etching process, while the dielectric layer 21 is removed using an etching process. According to a further embodiment, both, the electrode layer 31 and the dielectric layer 21 are polished.

The first electrode layer 31 includes, for example, an electrically conductive material, such as a metal or a highly doped polycrystalline semiconductor material. The first electrode layer 31 can be formed by employing a deposition process.

Referring to FIG. 1C, the dielectric layer 21 extends to the first surface 101. In the vertical cross sectional view illustrated in FIG. 1C, the first dielectric layer 21 has a U-shaped geometry with two legs extending to the first surface 101, namely a first leg of the first dielectric layer 21 between a first sidewall of the (former) trench 11 and the first electrode layer 31, and a second leg of the first dielectric layer 21 between a second sidewall of the former trench 11 and the first electrode layer 31.

In next method steps an upper section of at least one of these legs of the first dielectric layer 21 extending to the first surface 101 is removed to form at least one first gap in the first surface 101. “An upper section” of the dielectric layer 21 is a section extending to the first surface 101. Referring to FIG. 1D, the upper portions of both legs of the first dielectric layer 21 can be removed to form a first gap 12₁ and a second gap 12₂ in the first surface 101. These gaps 12₁, 12₂ are formed by removing the first dielectric layer 21 down to a desired depth. Removing the dielectric layer 21 may include an etching process that etches the dielectric material of the first dielectric layer 21 selectively relative to the material of the semiconductor body 100 and the material of the first electrode layer 31. A depth of the first gaps 12₁, 12₂ can be adjusted by suitably selecting a duration of the etching process. The “depth” of each gap 12₁, 12₂ is the dimension in a direction perpendicular to the first surface 101. The first and second gaps 12₁, 12₂ can be produced to have the same depth. In this case, the first dielectric layer 21 on the first and second sidewalls of the former first trench 11 is subject to the same etching process. However, the first and second gaps 12₁, 12₂ could also be produced to have different depths. First and second gaps 12₁, 12₂ with different depths may, for example, be produced by covering a first leg of the dielectric layer 21 on the first surface 101 while etching a second leg of the dielectric layer 21. The first leg is then uncovered and both legs are commonly etched. Since the second leg is subject to the etching process for a longer time a second gap 12₂ obtained by removing an upper section of the second leg is deeper than the first gap 12₁ obtained by removing an upper section of the first leg.

Forming two gaps 12₁, 12₂ is only an example. According to a further embodiment, one of the legs of the first dielectric layer 21 is covered on the first surface 101 during the etching process, so that only one gap is formed in the semiconductor body 100.

Referring to FIG. 1E, at least one second trench 13₁, 13₂ is formed by widening the at least one first gap 12₁, 12₂. In the embodiment illustrated in FIG. 1D, in which two gaps 12₁, 12₂ are formed, two second trenches 13₁, 13₂ are formed by widening these first gaps 12₁, 12₂. Widening the at least one first gap 12₁, 12₂ may include an etching process that isotropically etches the semiconductor body 100 and the first electrode layer 31 adjoining the gaps 12₁, 12₂. A width of the second trenches 13₁, 13₂ is, for example, dependent on a duration of the etching process, where the width increases with increasing duration of the etching process. A width of the at least one second trench 13₁, 13₂ is the dimension in a lateral direction of the semiconductor body 100. During this etching process the semiconductor body 100 and the first electrode layer 31 may also be etched at the first surface 101. However, this would be acceptable.

Referring to FIG. 1F, a second dielectric layer 22₁, 22₂ is formed on the bottom and the sidewalls of the at least one second trench 13₁, 13₂. Concerning the composition and the methods for producing this at least one second dielectric layer 22₁, 22₂ the explanation provided above concerning the first dielectric layer 21 applies accordingly, so that reference to this explanation is made. Since in the embodiment illustrated in FIG. 1E, two second trenches 13₁, 13₂ are formed, two second dielectric layer 22₁, 22₂ are formed, namely in each of the two second trenches 13₁, 13₂.

Referring to FIG. 1G, a second electrode layer 32₁, 32₂ is formed on the second dielectric layer 22₁, 22₂ in the at least one second trench 13₁, 13₂. Like the first electrode layer 31 in the first trench 11, the second electrode layer 32₁, 32₂ may completely fill the at least one second trench 13₁, 13₂, or may only cover the second dielectric layer 22₁, 22₂ in the at least one second trench 13₁, 13₂, so as to leave a residual trench. In the embodiment illustrated in FIG. 1G, two second electrode layers 32₁, 32₂ are formed, one second electrode layer 32₁, 32₂ in each second trench 13₁, 13₂. Concerning the composition and the methods for producing this at least one second electrode layer 32₁, 32₂ the explanation provided above concerning the first electrode layer 31 applies accordingly, so that reference to this explanation is made.

The capacitive structure obtained through the method explained before and illustrated in FIG. 1G includes four capacitances, a first capacitance C₁ between the second electrode layer 32₁ in one of the second trenches and the first electrode layer 31 in the first trench, a second capacitance C₂ between the second electrode layer 32₂ in the other one of the second trenches and the first electrode layer 31 in the first trench, a third capacitance C₃ between the second electrode layer 32₁ in the first one of the second trenches and the surrounding semiconductor material of the semiconductor body 100, and a fourth capacitance C₄ between the second electrode layer 32₂ in the other one of the second trenches and the surrounding semiconductor material of the semiconductor body 100.

Which of these capacitances C₁-C₄ is used, is dependent on the specific application. These capacitances can be connected in a conventional manner to other semiconductor devices or to terminals of other semiconductor devices (not illustrated) integrated in the semiconductor body 100. Of course, these capacitances C₁-C₄ may also be connected to external electronic devices, which are electronic devices not integrated in the semiconductor body 100.

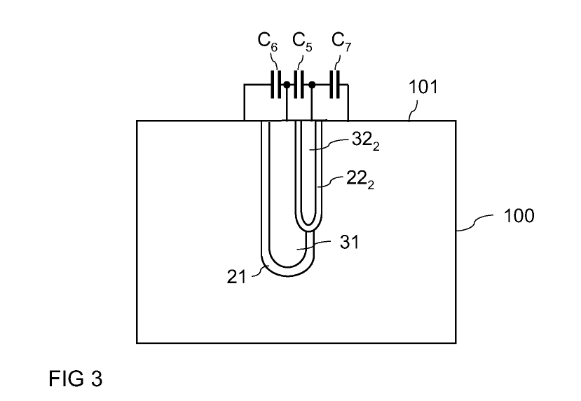

FIG. 3 illustrates a vertical cross sectional view of a capacitive structure obtained through a modification of the method illustrated in FIGS. 1A to 1G. The capacitive structure according to FIG. 3 includes only one second trench with the second electrode layer 32₂. This capacitive structure is obtained by modifying the method steps illustrated in FIGS. 1B to 1G such that only one first gap, namely in this specific example the second gap 12₂ along the second sidewall of the former first trench 11, is formed, so that only one second trench 13₂ is formed. Modifying the method in this way only includes the additional method step of covering one leg of the first dielectric layer 21, in this specific embodiment the leg extending along the first sidewall of the former first trench 11, on the first surface 101.

The capacitive structure illustrated in FIG. 3 includes three capacitances, namely a first capacitance C₅ between the second electrode layer 32₂ and the first electrode layer 31, a second capacitance C₆ between the first electrode layer 31 and the semiconductor material of the surrounding semiconductor body 100, and a third capacitance C₇ between the second electrode layer 32₂ and the semiconductor material of the surrounding semiconductor body 100.

The method explained with reference to FIGS. 1A to 1G and FIG. 3 is a multi-level method which results in a multi-level capacitive structure, wherein in the embodiments explained before the method is 2-level method resulting in a 2-level capacitive structure. Each method level includes the forming of at least one capacitive structure in a trench. In the method illustrated in FIGS. 1A to 1G a first method level includes forming one 1st level capacitive structure with the first dielectric layer 21 and the first electrode layer 31 in the first trench 11, and a second method level includes forming 2nd level capacitive structures with the second dielectric layer 22₁, 22₂ and the second electrode layers 32₁, 32₂ in the second trenches. By virtue of the method steps illustrated in FIGS. 1D to 1G, capacitances of the 2nd level capacitive structure are self-adjusted to the sidewalls of the first trench 11.

In the following, n denotes the number of method levels and in the multi-level method and, therefore, denotes the number of capacitive structure levels in the capacitive structure. The method is, of course, not restricted to n=2 method levels.

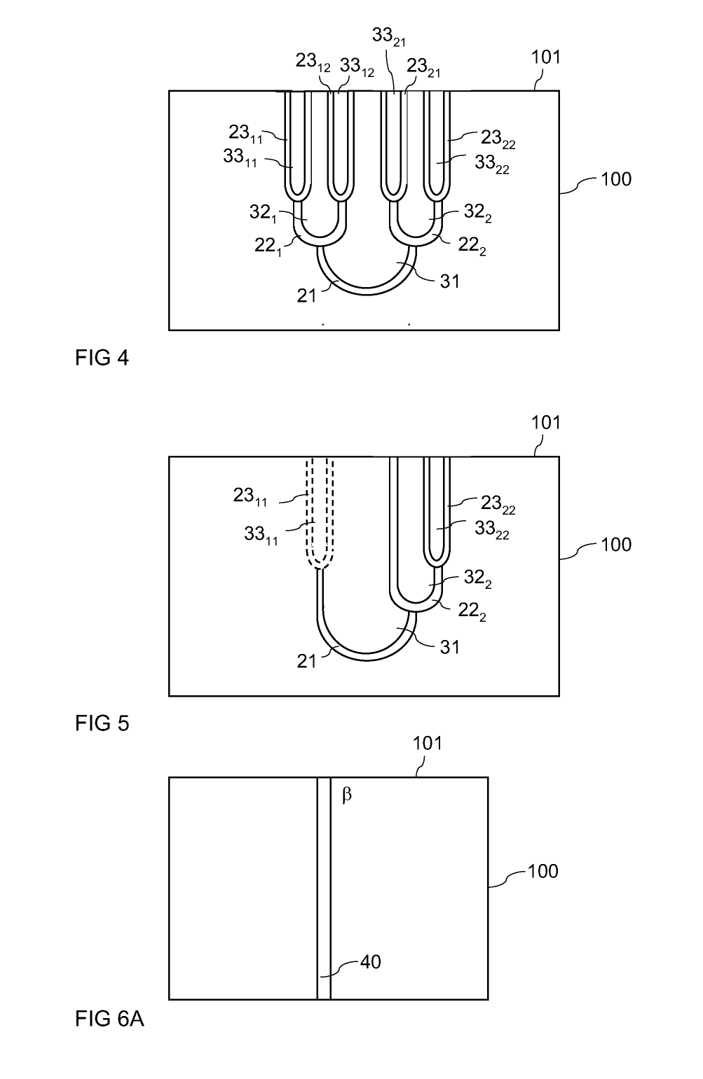

FIG. 4 illustrates a vertical cross sectional view of a 3-level capacitive structure obtained through a method including n=3 method levels. The capacitive structure illustrated in FIG. 4 can be obtained based on the 2-level capacitive structure illustrated in FIG. 1G by forming third trenches, by forming third dielectric layers 23₁₁, 23₁₂, 23₂₁, 23₂₂ in these third trenches, and by forming third electrode layers 33₁₁, 33₁₂, 33₂₁, 33₂₂ in these third trenches. In this method, the third trenches are self-adjusted to trench sidewalls of the former second trenches (13₁, 13₂) in which the 2nd level capacitive structures with the second dielectric layers 22₁, 22₂ and the second electrode layers 32₁, 32₂ are implemented. Like in the method steps illustrated in FIGS. 1D and 1E, forming the third trenches includes forming gaps by removing upper sections of the second dielectric layers 22₁, 22₂, that were formed along the sidewalls of the former second trenches 13₁, 13₂, and by widening these trenches by, for example, employing an isotropic etching process.

As can be seen from FIG. 4, the number of capacitive structures can be doubled from method level to method level or from a capacitive structure of one level to a capacitive structure of a next level. In the first method level, one 1st level capacitive structure including the first dielectric layer 21 and the first electrode layer 31 is produced. In the second method level two 2nd level capacitive structures with the second dielectric layers 22₁, 22₂ and the second electrode layers 32₁, 32₂ can be formed, and in the third method level four 3rd level capacitive structures with the third dielectric layers 23₁₁, 23₁₂, 23₂₁, 23₂₂ and the third electrode layers 33₁₁, 33₁₂, 33₂₁, 33₂₂ are formed. In general, in a method with n method levels 2ⁿ⁻¹ capacitive structures can be formed in the n-th method level or in the n-th level capacitive structure, respectively. Altogether

$${2}^{n} - 1 = {\sum }_{i = 1}^{n} {2}^{i - 1}$$

capacitive structures can be formed through the method. However, by selectively covering the dielectric layers extending to the first surface 101 in each method level as described above, the number of capacitive structures to be produced can be adjusted.

FIG. 5 illustrates a vertical cross sectional view of a 3-level capacitive structure according to a further embodiment. The capacitive structure illustrated in FIG. 5 only includes one capacitance in each level. This structure can be obtained from the capacitive structure illustrated in FIG. 3 by forming one additional capacitive structure self-adjusted to the second dielectric layer 22₂ along one of the sidewalls of the former second trench 13₂.

In the capacitive structures explained before, individual capacitances of capacitive structures of the 2nd level and of levels higher than the second level, are produced self-adjusted to at least one sidewall of at least one trench produced in a preceding method level. Let i be a method level, wherein i>1, then capacitances of the i-th capacitive structure are self-adjusted to trench sidewalls of trenches in which dielectric layers and electrode layers of capacitances of an m-th level capacitive structure are implemented. According to one embodiment, m=i-1, so that the capacitances of the i-th level capacitive structure are self-adjusted to capacitances of the (i-1)-th capacitive structure produced in the directly preceding method level i-1.

However, m could also be smaller than i-1, so that the capacitances of the i-th level capacitive structure are not self-adjusted to capacitances of the (i-1)-th capacitive structure produced in the directly preceding method level i-1, but are self adjusted to capacitances produced in a method level even before the (i-1)-th level. This is illustrated in dashed lines in FIG. 5. In FIG. 5, the dashed lines illustrate a capacitance of the 3rd level capacitive structure that is self-adjusted to the capacitance of the 1st level capacitive structure, so that in this embodiment i=3 and m=1. This capacitance of the 3rd level capacitive structure includes a third dielectric layer 23₁₁ and a third electrode layer 33₁₁.

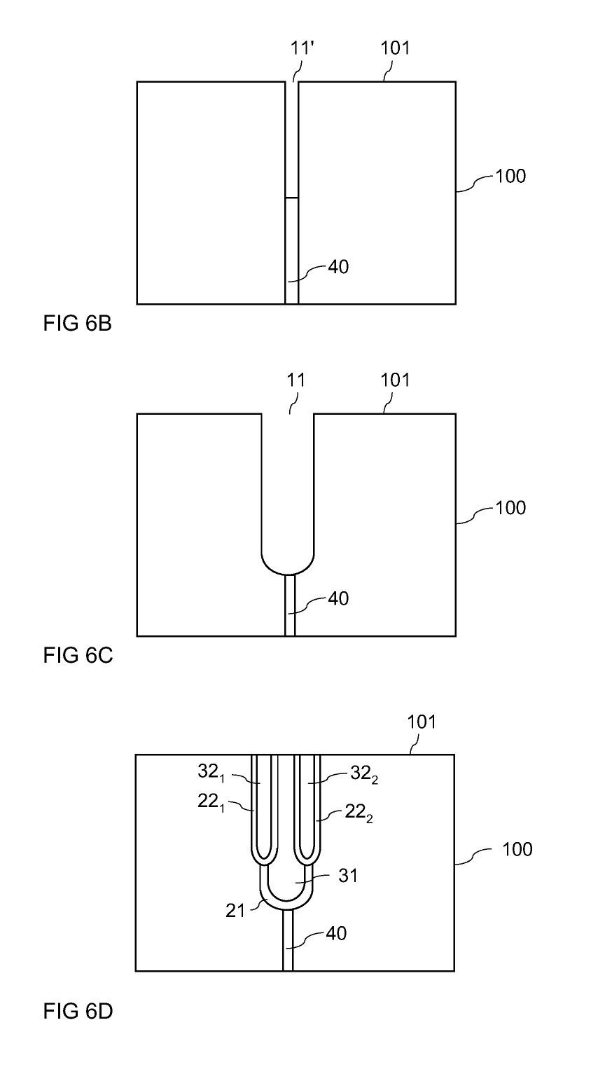

In the method explained with reference to FIG. 1A, the position of the first trench 11 is, for example, defined by the etch mask 200. According to a further embodiment explained with reference to FIGS. 6A to 6D the first trench 11 is produced self-adjusted to a vertical dielectric layer 40 in the semiconductor body 100. In connection with the present description the term “vertical dielectric layer 40” denotes a dielectric layer that basically extends in a vertical direction of the semiconductor body 100. However, an angle β between the dielectric layer 40 and the first surface 101 is not necessarily 90°. According to one embodiment, this angle is between 90° and 100° for example.

Referring to FIG. 6B, an upper portion of the vertical dielectric layer 40 is removed to form a gap 11′ in the first surface 101. Referring to FIG. 6C the first trench 11 is then formed by widening gap 11′. Widening the gap 11′ includes, for example, an isotropical etching process.

FIG. 6D shows a vertical cross sectional view of a 2-level capacitive structure that is obtained when applying the method steps illustrated in FIGS. 1B to 1G to the structure illustrated in FIG. 1C. This capacitive structure is self-adjusted to the vertical dielectric layer 40, where the 1st level capacitive structure with the first dielectric layer 21 and the first electrode layer 31 is adjusted to the vertical dielectric layer 40, and where the 2nd level capacitive structures with the second dielectric layers 22₁, 22₂ and the second electrode layers 32₁, 32₂ are adjusted to the first level capacitive structure.

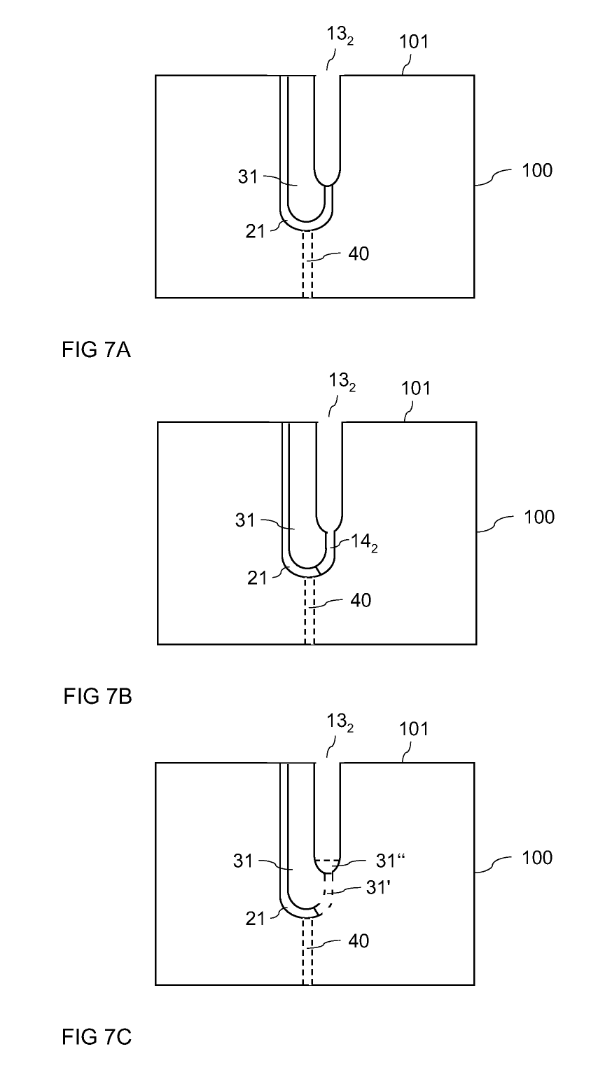

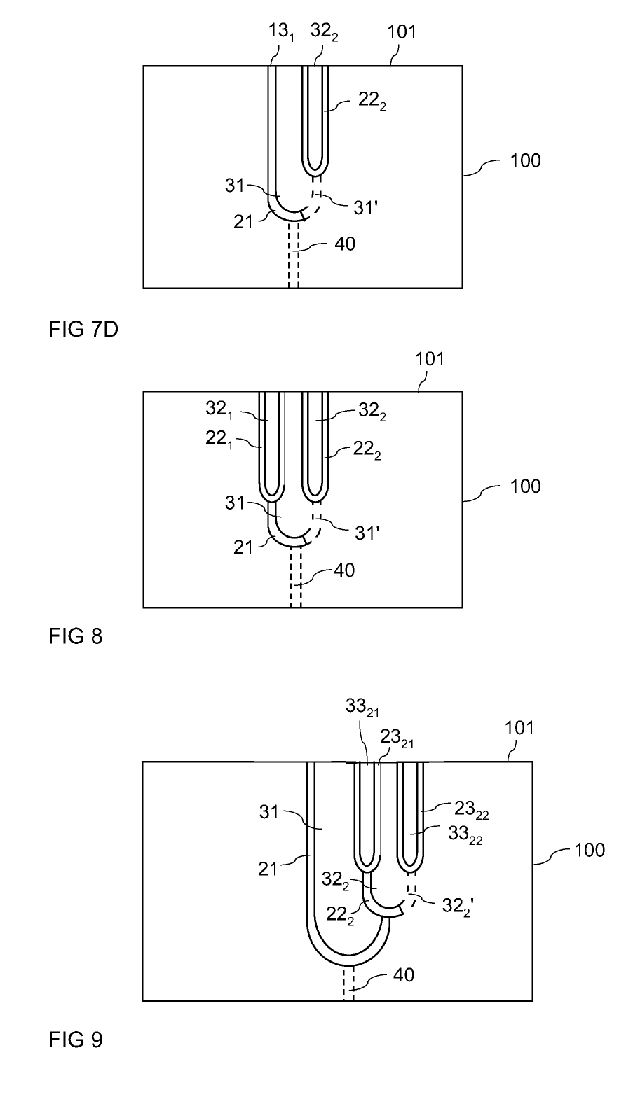

FIGS. 7A to 7B illustrate a modification of the method explained with reference to FIGS. 1A to 1G and FIG. 2. In this method, the electrode layer of one capacitive structure, such as the first electrode layer 31 of the 1st level capacitive structure, is electrically connected to the surrounding semiconductor material of the semiconductor body 100. As illustrated in dashed lines in FIGS. 7A to 7D, the overall capacitive structure is optionally self-adjusted to a vertical dielectric layer 40 arranged in the semiconductor body 100.

Connecting the electrode layer of one capacitive structure to the semiconductor material (or to an electrode layer of a capacitive structure produced in a preceding method level, as will be explained below) includes additional method steps after having formed the at least one trench in the next method level. FIG. 7A shows a vertical cross sectional view of the semiconductor body 100 after having produced the first capacitive structure with the first dielectric 21 and the first electrode layer 31, and after having produced one second trench 13₂.

Referring to FIG. 7B, the first dielectric layer 21 is removed below the bottom of the second trench 13₂ to form a further gap 14₂ at the bottom of the second trench 13₂. Referring to FIG. 7C, the gap 14₂ below the bottom of the second trench 13₂ is filled with a connecting material 31′, so as to electrically connect the first electrode layer 31 with the surrounding semiconductor material. According to one embodiment, the first electrode layer 31 is a semiconductor layer. In this embodiment, filling the gap 14₂ includes, for example, an epitaxial process in which semiconductor material is epitaxially grown in the gap 14₂ so as to connect the first electrode layer 31 with the surrounding semiconductor material. In this method it is not absolutely necessary to completely fill the gap 14₂, but to provide an electrical connection between the first electrode layer 31 and the surrounding semiconductor material. In FIG. 7C, reference character 31′ denotes the connecting material. Dependent on the type of connecting material and its production an interface between the first electrode layer 31 and the connecting material 31′ and between the connecting material 31′ and the semiconductor body 100 is visible or is not visible. Thus, the connecting material 31′ is illustrated in dashed lines in FIG. 7C. When the gap 14₂ is at least partly filled in order to form the connecting material or connection region 31′, an electrically conductive material may also be formed or deposited on the bottom and the sidewalls of the second trench 13₂. However, this is not explicitly illustrated in FIGS. 7A to 7C.

Additionally or alternatively to forming the connection region 31′ in a gap 14₂ below the second trench 13₂ a further connection region 31″ is formed at the bottom of the trench 13₂ between the first electrode layer 31 and the surrounding semiconductor material. This connection region 31″ is illustrated in dashed lines in FIG. 7B. The further connection region 31″ includes an electrically conducting or semiconducting material. According to one embodiment, the further connection region 31″ is formed by an epitaxial process in which a semiconductor material is grown on the bottom of the second trench 13₂. In this process, a semiconductor material is also grown on the sidewalls of the trench 13₂. However, this is not shown in FIG. 7B. When only the further connection region 31″ is formed, the steps of forming the gap 14₂ can be omitted. In this case, the further connection region 31″ is directly formed on the bottom of the second trench 13₂. When both, the first and the second connection regions 31′, 31″ are to be formed, a common process can be used, such as one deposition or one epitaxial growth process, to produce the connection region 31′ in the gap 14₂ and the further connection region 31″ on the bottom of the second trench 13₂.

Although connection regions illustrated in the following embodiments are connection regions formed in gaps below trenches, these connection regions could also be replaced by further connection regions, corresponding to the further connection region 31″ illustrated in FIG. 7B, at the bottom of trenches, or that those further connection regions may be provided additionally.

Referring to FIG. 7D, the method further includes forming the second dielectric layer 22₂ on the bottom and the sidewalls of the second trench 13₂, and forming the second electrode layer 32₂ in the second trench 13₂. By virtue of the electrical connection between the first electrode layer 31 and the semiconductor material, the capacitive structure of FIG. 7D includes only one capacitance, namely a capacitance between the semiconductor body 100 and the second electrode layer 32₂.

Although the first dielectric layer 21 and the first electrode layer 31 do not form a capacitance when the first electrode layer 31 is electrically connected to the semiconductor material of the semiconductor body 100, this structure will still be referred to as a capacitive structure in the following.

The method explained with reference to FIGS. 7A to 7D is not restricted to form an electrical connection between the first electrode layer 31 and the surrounding semiconductor material. Instead, this method can be used to form an electrical connection between each of the electrode layers of one capacitive structure and the electrode layer of a capacitive structure formed in a preceding method level or the semiconductor material.

FIG. 8 illustrates a vertical cross sectional view of a 2-level capacitive structure in which the first electrode layer 31 of the 1st level capacitive structure is electrically connected to the semiconductor body 100, and which includes two 2nd level capacitive structures. This capacitive structure can be obtained by modifying the method explained with reference to FIGS. 1A to 1G using the method steps illustrated in FIGS. 7A to 7D.

FIG. 9 illustrates a vertical cross sectional view of a 3-level capacitive structure including a 1st level capacitive structure with a first dielectric layer 21 and a first electrode layer 31, a 2nd level capacitive structure with one second dielectric layer 22₂ and one second electrode layer 32₂, and with two 3rd level capacitive structures with two third dielectric layers 23₂₁, 23₂₂ and two third electrode layers 33₂₁, 33₂₂. The second electrode layer 32₂ is electrically connected to the semiconductor material of the semiconductor body 100 through a connection material 32₂′ produced below the third capacitive structure, namely that third capacitive structure that adjoins the semiconductor body 100.

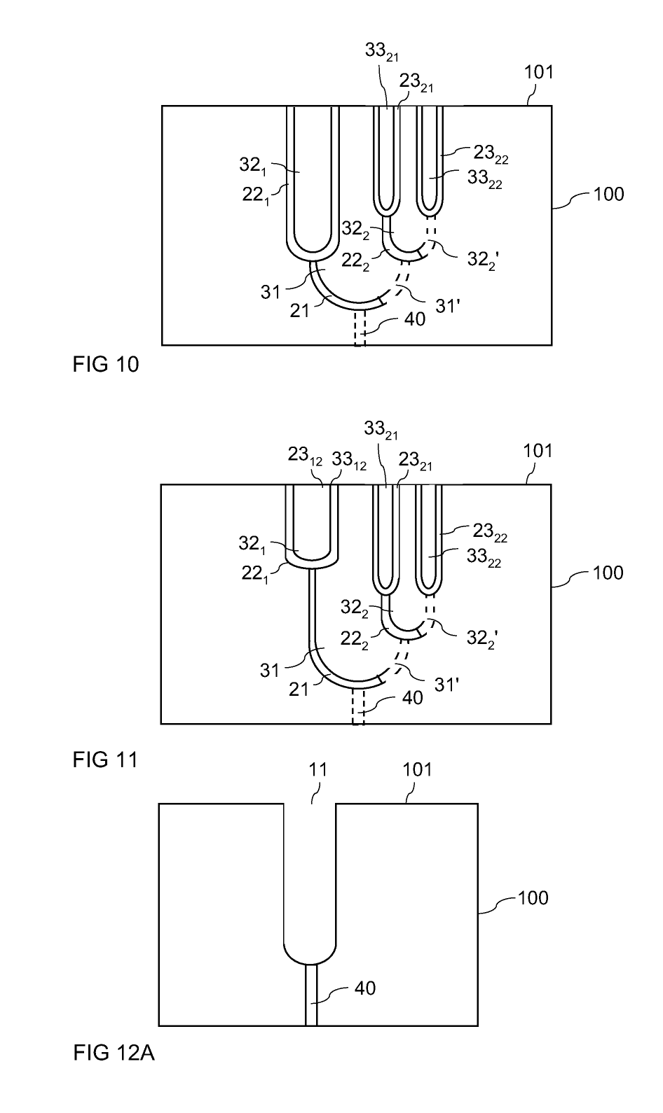

FIG. 10 illustrates a further embodiment of a capacitive structure with three levels. This capacitive structure includes one 1st level capacitive structure with a first dielectric layer 21 and a first electrode layer 31, two 2nd level capacitive structures each having one second dielectric layer 22₁, 22₂ and one second electrode layer 32₁, 32₂, and two 3rd level capacitive structures, wherein these two 3rd level capacitive structures are adjusted to one of the 2nd level capacitive structures, namely the second capacitive structure arranged in the right section of FIG. 10. In this embodiment, the first electrode layer 31 is electrically connected to the semiconductor material through a connection material 31′, and the second capacitive structure 32₂ that has the third capacitive structures adjusted thereto has the second electrode layer 32₂ electrically connected to the semiconductor material through a second connection material 32₂′.

FIG. 11 illustrates a capacitive structure which is a modification of the 3-level capacitive structure illustrated in FIG. 10. While in the capacitive structure of FIG. 10 the second capacitive structures are formed in trenches that have the same depth, the capacitive structure illustrated in FIG. 11 has two 2nd level capacitive structures, namely a second capacitive structure with a dielectric layer 22₁ and a second electrode layer 32₁ illustrated in the left part of FIG. 11, and a second capacitive structure with a second dielectric layer 22₂ and a second electrode layer 32₂ illustrated in the right part of FIG. 11. In this embodiment, the second capacitive structure illustrated in the left part does not extend as deep into the semiconductor body as the second capacitive structure illustrated in the right part. This can be obtained by etching the trenches in which the second capacitive structures are formed with different trench depths.

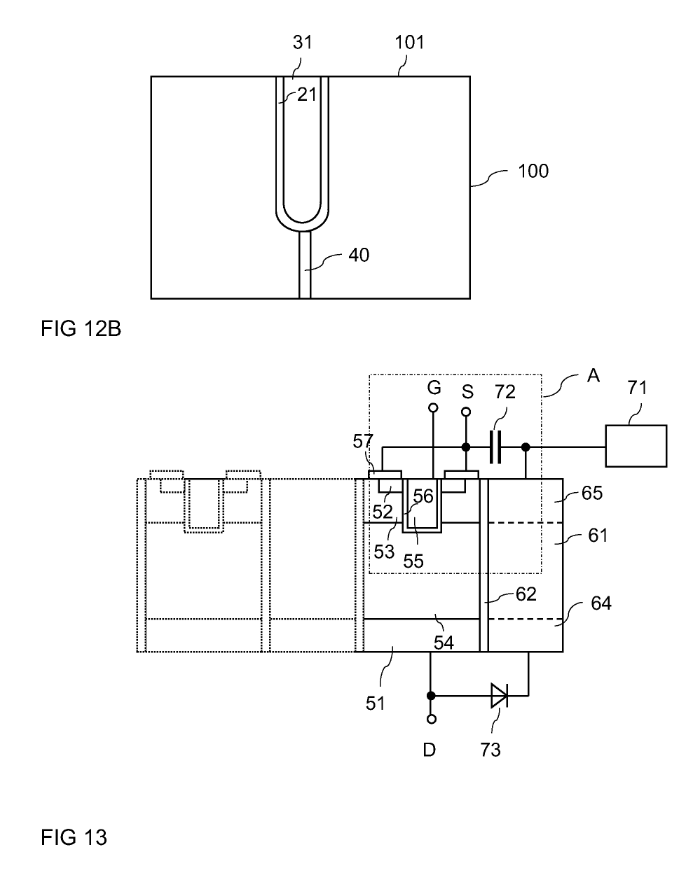

FIGS. 12A and 12B illustrate a further method for producing one (1st level) capacitive structure in a semiconductor body 100. This capacitive structure is self-adjusted to a vertical dielectric layer 40. Referring to FIG. 12A, this method includes forming a first trench 11 self-adjusted to the vertical dielectric layer 40. Referring to FIG. 12B, a first dielectric layer 21 is formed on the sidewalls and the bottom of the first trench 11, and a first electrode layer 31 is formed on the first dielectric layer 21 in the first trench 11. The first electrode layer 31 may completely fill the first trench 11 or may leave a residual trench as previously described herein e.g. with reference to FIG. 1C.

The capacitive structures explained above can be used in a wide field of integrated electronic circuits and electronic devices. According to one embodiment, the capacitive structure is implemented in a new type of MOSFET which includes a drift control region adjacent to a drift region, dielectrically insulated from the drift region and for controlling a conductive channel in the drift region when the MOSFET is in an on-state (switched on).

A vertical cross sectional view of one embodiment of this MOSFET is illustrated in FIG. 13. The MOSFET of FIG. 13 is implemented as a vertical MOSFET in which a current flow direction corresponds to a vertical direction of the MOSFET. However, the basic operating principle explained in the following also applies to lateral MOSFETs.

Referring to FIG. 13, the MOSFET includes a drain region 51, a source region 52, a body region 53 and a drift region 54. The drain and source regions 51, 52 are arranged distant in the current flow direction, the body region 53 is arranged between the source region 52 and the drift region 54. The drain region 51 is electrically connected to a drain terminal D that is only schematically illustrated in FIG. 13. The source region 52 and the body region 53 are electrically connected to a source electrode 57 which forms or which is connected to a source terminal S.

The MOSFET further includes a gate electrode 55 which extends from the source region 52 through the body region 53 to or into the drift region 54, which is dielectrically insulated from these semiconductor regions by a gate dielectric 56, and which is connected to a gate terminal G. The gate dielectric 56 can be a conventional gate dielectric and include, for example an oxide or a nitride. In the example illustrated in FIG. 13, the gate electrode 55 is a trench electrode that is arranged in a trench of a semiconductor body in which the MOSFET is implemented. However, this is only an example. The gate electrode 55 could also be implemented as a planar electrode above the surface of the semiconductor body.

The MOSFET can be implemented as an n-type MOSFET or as a p-type MOSFET. In an n-type MOSFET, the source region 52 and the drain region 51 are n-doped while the body region 53 is p-doped. In a p-type MOSFET, the source region 52 and the drain region 51 are p-doped while the body region 53 is n-doped. The doping concentration of the drain region 51 and the source region 52 is, for example in the range of between 5E17 cm⁻³ and 1E21 cm⁻³. The doping concentration of the body region 53 is, for example, in the range of between 5E16 cm⁻³ and 5E18 cm⁻³.

The MOSFET can be implemented as an enhancement (normally-off) MOSFET or as a depletion (normally-on) MOSFET. In an enhancement MOSFET, the body region 53 extends to the gate dielectric 56. In a depletion MOSFET, the body region 53 at least along the gate dielectric 56 includes a channel region (not illustrated) of the same doping type as the source region 52.

In the type of MOSFET illustrated in FIG. 13, the drift region 54 can have the same doping type as the source region 52 and the drain region 51, but could also be doped complementarily to the source region 52 and the drain region 51, wherein at least a section of the drift region 54 between a vertical dielectric layer 62 which will be explained in the following and a channel region of the MOSFET may have the same doping type as the source region 52. The “channel region” of the MOSFET is a region of the body region 53 along the gate dielectric 56 where the gate electrode 55 controls a conducting channel. The doping concentration of the drift region 54 is, for example, in the range of between 1E12 cm⁻³ and 1E15 cm⁻³.

Referring to FIG. 13, the MOSFET further includes a drift control region 61 that is dielectrically insulated from the drift region 54 by the vertical dielectric layer 62. The vertical dielectric layer 62 acts as a drift control region dielectric. The drift control region 61 is configured to generate a conducting channel in the drift region 54 along the drift control region dielectric 62 when the MOSFET is in an on-state, so as to reduce the on-resistance of the MOSFET. The MOSFET, like a conventional MOSFET, is in its on-state, when an electrical potential is applied to the gate terminal G that causes a conducting channel in the body region 53 between the source region 52 and the drift region 54 along the gate dielectric 56, and when an electrical voltage is applied between the drain and the source terminals D, S. The conducting channel along the gate control region dielectric 62 is an accumulation channel when the drift region 54 has the same doping type as the source and drain regions 52, 51, and is an inversion channel, when the drift region 54 is doped complementarily to these regions.

The MOSFET further includes a biasing source 71 coupled to the drift control region 61. According to one embodiment (not illustrated) the biasing source 71 includes a rectifier element, such as a diode, connected between the gate terminal G and the drift control region 61. A capacitive element 72, such as a capacitor, is coupled between the drift control region 61 and a terminal for a reference potential, such as the source terminal S. Further, a rectifier element 73, such as a diode, is connected between the drain region 51 and a drain-sided end of the drift control region 61. Optionally, the rectifier element 73 is connected to a connection region 64 which has the same doping type as the drift control region 61, but a higher doping concentration.

The MOSFET may further include a semiconductor zone 65 doped complementarily to the drift control region 61. In this case, the biasing source 71 and the optional capacitive element 72 are connected to this semiconductor zone 65. According to one embodiment, the doping type of the drift control region 61 corresponds to the doping type of the drift region 54.

The operating principle of the MOSFET according to FIG. 13 is now explained. For explanation purposes it is assumed that the MOSFET is an n-type MOSFET with an n-doped drift zone 54, and that the drift control region 61 has the same doping type as the drift region 54. The biasing source 71 is configured to bias the drift control region 61 to have a positive potential relative to the electrical potential of the source terminal S (source potential), when the MOSFET is in the on-state. The MOSFET is in the on-state, when the drive potential applied to the gate terminal G generates a conducting channel in the body region 53 between the source region 52 and the drift region 54, and when a positive voltage is applied between the drain and the source terminals D, S. In the on-state, the drift control region 61, which has a higher electrical potential than the drift region 54, generates an accumulation channel along the gate control region dielectric 62 in the drift region 54. This accumulation channel significantly reduces the on-resistance as compared to a MOSFET without a drift control region.

The MOSFET is in the off-state when the channel in the body region 53 is interrupted. In this case, a depletion region expands in the drift region 54 beginning at a pn-junction between the body region 53 and the drift region 54. The depletion region expanding in the drift region 54 causes a depletion region also to expand in the drift control region 61, which, like the drift region 54, may include a monocrystalline semiconductor material. By virtue of a depletion region expanding in the drift region 54 and a depletion region expanding in the drift control region 61, a voltage across the drift control region dielectric 62 is limited. The capacitive storage element 72 serves to store electrical charges that are required in the drift control region 61 when the MOSFET is in its on-state. The rectifier element 73 allows charge carriers that are thermally generated in the drift control region 61 to flow to the drain region 51. The rectifier element 73 is connected up such that in the on-state of the MOSFET the drift control region 61 may assume a higher electrical potential than the potential at the drain terminal D.

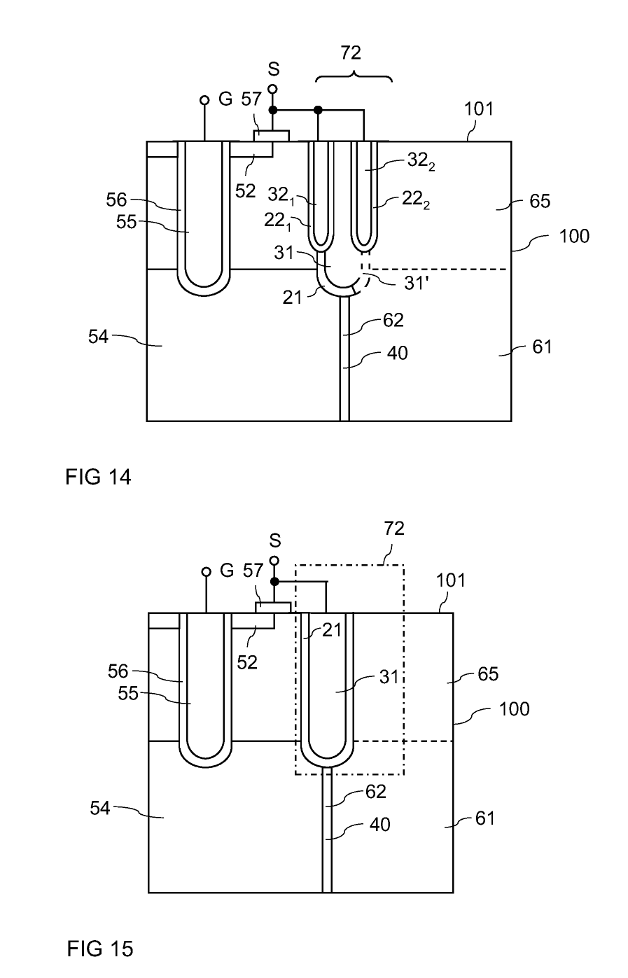

The MOSFET includes two capacitive elements, namely the capacitive element 72 for storing charge carriers from the drift control region 61 when the MOSFET is in the off-state, and the gate electrode 55 with the gate dielectric 56. One or both of these capacitive elements can be implemented using one of the capacitive structures explained before. Several embodiments are explained with reference to FIGS. 14 to 19 below. In these Figures vertical cross sectional views of the MOSFET are illustrated. In these Figures only those sections of the semiconductor body are illustrated in which the gate electrode 55 and the gate dielectric 56 and the capacitive element are implemented. This corresponds to a section A illustrated in dashed and dotted lines in FIG. 13. FIG. 13 only illustrates one transistor cell of the MOSFET, where the MOSFET may include a plurality of these transistor cells connected in parallel. An additional transistor cell is illustrated in dotted lines in FIG. 13.

In the embodiment illustrated in FIG. 14, the gate electrode 55 is implemented as a conventional trench electrode arranged distant to the drift control region dielectric 62. The capacitive element is implemented using the capacitive structure illustrated in FIG. 8. This capacitive structure is a 2-level structure with two 2nd level capacitive structures and with the first electrode layer 31 of the 1st level capacitive structure connected to the drift control region 61. The capacitive structure is implemented self-adjusted to the drift control region dielectric 62 which acts as the vertical dielectric layer 40 explained before. The capacitive element 72 is formed between the drift control region 61 or the optional complementary region 65 and the second electrode layers 32₁, 32₂ of the 2nd level capacitive structures. These second electrode layers 32₁, 32₂ are both connected to a terminal for a reference potential, such as the source terminal.

In the embodiment illustrated in FIG. 15, the gate electrode 55 is implemented as a conventional trench electrode arranged distant to the drift control region dielectric 62. The capacitive element is implemented using the capacitive structure illustrated in FIG. 12B. This capacitive structure is a 1-level structure with the first dielectric layer 21 and the first electrode layer 31. The capacitive structure is implemented self-adjusted to the drift control region dielectric 62 which acts as the vertical dielectric layer 40 explained before. The capacitive element 72 is formed between the drift control region 61 or the optional complementary region 65 and the first electrode layer 31 that is connected to a terminal for a reference potential, such as the source terminal.

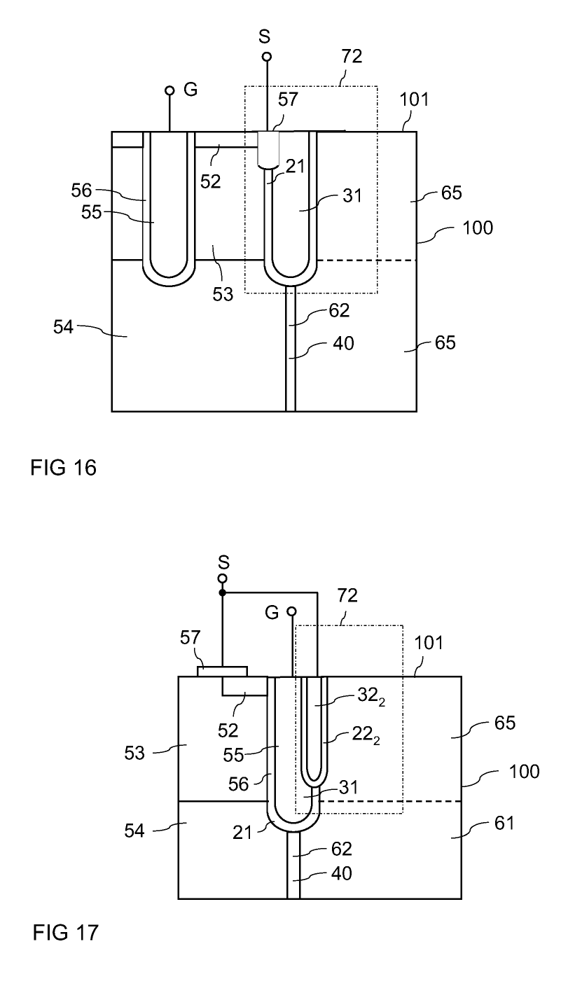

FIG. 16 illustrates a modification of the MOSFET of FIG. 15. While in the MOSFET according to FIG. 15, as well as in the MOSFETs according to FIGS. 13 and 14, the source electrode 57 is arranged above the first surface 101 and electrically contacts the source region 52 as well as a section of the body region 53 extending to the first surface 101, in the MOSFET to FIG. 16 the source electrode 57 is arranged in a trench which from the first surface 101 extends through the source region 52 into the body region 53. The trench with the source electrode 57 is arranged above that section of the dielectric layer 21 of the capacitive structure that adjoins the body region 53. The trench with the source electrode 57 can be produced self-adjusted to the dielectric layer 21 by method steps similar to those explained with reference to FIGS. 1D and 1E, namely by first forming a gap in the first surface 101 by removing an upper section of the dielectric layer 21, and by widening the trench. An upper section of the dielectric layer 21 is a section adjoining the first surface 101. Widening the trench may, for example, include an isotropic etching process. The trench is then filled with an electrically conducting material, such as a metal or a highly doped polycrystalline semiconductor material, so as to form the source electrode 57.

In the embodiment illustrated in FIG. 17, both the gate electrode 55 and the capacitive element 72 are implemented using a self-adjusted capacitive structure. In the embodiment according to FIG. 17, this capacitive structure is the capacitive structure according to FIG. 3. This capacitive structure is a 2-level capacitive structure with one 1st level capacitive structure including the first dielectric layer 21 and the first electrode layer 31 forming the gate dielectric 56 and the gate electrode 55, respectively. The 2nd level includes only one capacitive structure with a second dielectric layer 22₂ and a second electrode layer 32₂. The 2nd level capacitive structure is arranged distant to the body region 53 in a lateral direction of the semiconductor body 100 and is arranged between the first electrode layer 31 and the drift control region 61 or the optional semiconductor region 65, respectively.

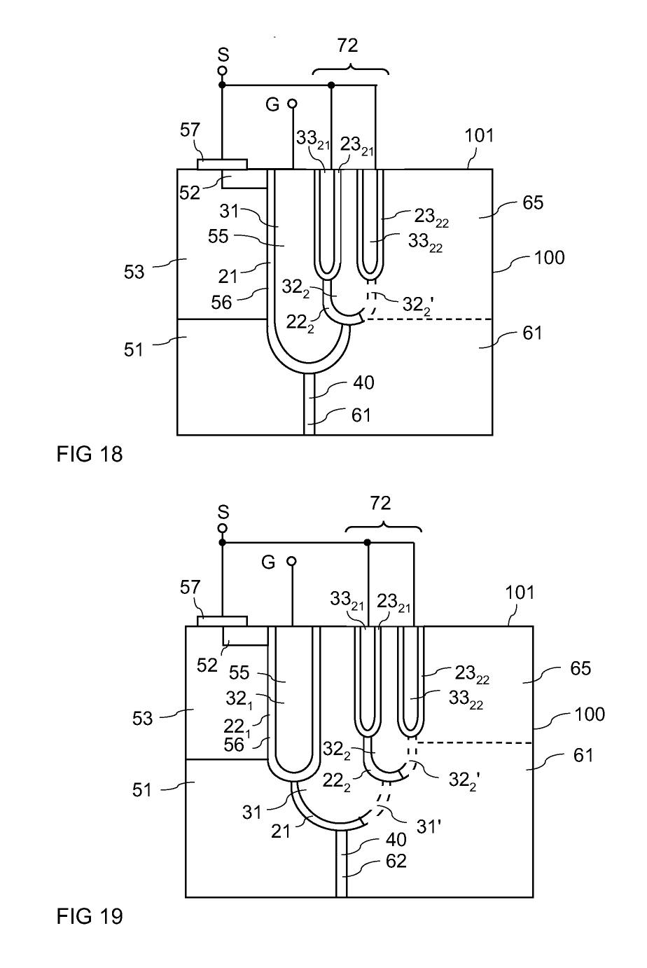

In the embodiment illustrated in FIG. 18, the gate structure with the gate electrode 55 and the gate dielectric 56 and the capacitive element 72 are formed by a 3-level capacitive structure. The gate dielectric 56 and the gate electrode 55 are again formed by the 1st level capacitive structure with the first dielectric layer 21 and the first electrode layer 31. The first dielectric layer 21 adjoins the body region 53 and dielectrically insulates the body region 53 from the first electrode layer 31 forming the gate electrode 55. The 3-level capacitive structure according to FIG. 18 includes one 2nd level capacitive structure with a second dielectric layer 22₂ and a second electrode layer 32₂ arranged distant to the body region 53 in a lateral direction with the semiconductor body 100. The second electrode layer 32₂ is electrically connected to the drift control region 61 or the optional semiconductor region 65 through a connection material 32₂′. Two 3rd level capacitive structures that are self-adjusted to the second capacitive structure form the capacitive element 72. The third electrode layers 33₂₁, 33₂₂ are electrically connected to a terminal for a reference potential, such as the source terminal S. The 3rd level capacitive structures further include third dielectric layers 23₂₁, 23₂₂ dielectrically insulating the third electrode layers 33₂₁, 33₂₂ from electrode layers of lower level capacitive structures, such as the first electrode layer 31 of the first capacitive structure and the second electrode layer 32₂ of the second capacitive structure, and the drift control region 61, respectively.

FIG. 19 illustrates a modification of the MOSFET according to FIG. 18. In the MOSFET according to FIG. 19, the capacitive structure is also a 3-level capacitive structure, but includes two 2nd-level capacitive structures, namely a first 2nd-level capacitive structure with a second dielectric layer 22₁ and a second electrode layer 32₁ forming the gate dielectric 56 and the gate electrode 55, respectively. The capacitive element 72 is implemented like in an embodiment illustrated in FIG. 18 by two 3rd-level capacitive structures that are self-adjusted to the 2nd-level capacitive structure.

In the embodiments illustrated in FIGS. 17 to 19, the source electrode 57 is arranged above the first surface 101 of the semiconductor body 100. However, this is only an example. The source electrode 57 could also be implemented in a trench that is self-adjusted to the gate dielectric 56 as illustrated in FIG. 16.

Spatially relative terms such as “under”, “below”, “lower”, “over”, “upper” and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, an and the are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A method for producing a capacitive structure in a semiconductor body, comprising:
forming a first trench in a first surface of the semiconductor body;
forming a first dielectric layer on sidewalls and a bottom of the first trench;
forming a first electrode layer on the first dielectric layer;
forming at least one second trench by removing at least one part of the first dielectric layer to form a first gap in the first surface, and by widening the first gap;
forming a second dielectric layer on sidewalls and a bottom of the at least one second trench; and
forming a second electrode layer on the second dielectric layer.

2. The method of claim 1, wherein forming the first electrode layer on the first dielectric layer comprises completely filling the first trench.

3. The method of claim 1, wherein forming the second electrode layer on the second dielectric layer comprises completely filling the second trench.

4. The method of claim 1, further comprising:
forming at least one third trench by removing at least one part of the second dielectric layer to form a second gap in the first surface, and by widening the second gap;
forming a third dielectric layer on sidewalls and a bottom of the at least one third trench;
forming a third electrode layer on the third dielectric layer.

5. The method of claim 1, further comprising forming a connection region on the bottom of the at least one second trench before forming the second dielectric layer.

6. The method of claim 5, wherein the connection region includes an electrically conductive material or a semiconductor material.

7. The method of claim 1, further comprising:
removing a section of the first dielectric layer below a bottom of the at least one second trench to form a further gap; and
forming a connection region in the further gap, before forming the second dielectric layer in the at least one second trench.

8. The method of claim 1, further comprising:
providing the semiconductor body with a vertical dielectric layer; and
forming the first trench self-adjusted to the vertical dielectric layer.

9. The method of claim 8, wherein forming the first trench comprises:
forming a gap in the first surface by removing a section of the vertical dielectric layer; and
widening the gap to form the first trench.

10. A method for forming a multi-level capacitive structure, comprising:
forming a 1st level capacitive structure in a semiconductor body, the 1st level capacitive structure comprising a first trench, a first dielectric layer on sidewalls and a bottom of the first trench and a first electrode layer on the first dielectric layer; and
forming at least one 2nd level capacitive structure in the semiconductor body, the at least one 2nd level capacitive structure comprising a second trench adjusted to one sidewall of the first trench, a first dielectric layer on sidewalls and a bottom of the second trench and a second electrode layer arranged on the second dielectric layer.

11. The method of claim 10, further comprising forming at least one higher than the 2nd level capacitive structure in the semiconductor body, the at least one higher than the 2nd level capacitive structure comprising a further trench adjusted to one sidewall of a trench of one capacitive structure of a lower level than the higher than the 2nd level capacitive structure.

12. The method of claim 11, further comprising forming at least two higher than the 2nd level capacitive structures having different levels.

13. A multi-level capacitive structure, comprising:
a 1st level capacitive structure in a semiconductor body, the 1st level capacitive structure comprising a first trench, a first dielectric layer on sidewalls and a bottom of the first trench and a first electrode layer on the first dielectric layer; and
at least one 2nd level capacitive structure in the semiconductor body, the at least one 2nd level capacitive structure comprising a second trench adjusted to one sidewall of the first trench, a first dielectric layer on sidewalls and a bottom of the second trench and a second electrode layer on the second dielectric layer.

14. The multi-level capacitive structure of claim 13, further comprising at least one higher than the 2nd level capacitive structure in the semiconductor body, the at least one higher than the 2nd level capacitive structure comprising a further trench adjusted to one sidewall of a trench of one capacitive structure of a lower level than the higher than the 2nd level capacitive structure.

15. The multi-level capacitive structure of claim 14, further comprising at least two higher than the 2nd level capacitive structures having different levels.

16. A transistor device, comprising:
a drain region, a source region, a body region and a drift region arranged in a semiconductor body, the body region arranged between the source region and the drift region, and the drift region arranged between the body region and the drain region;
a gate structure comprising a gate electrode arranged adjacent the body region, and a gate dielectric arranged between the gate electrode and the body region;
a drift control region arranged adjacent the drift region in a lateral direction of the semiconductor body, and a drift control region dielectric arranged between the drift control region and the drift region and extending in a vertical direction of the semiconductor body;
a capacitive element electrically coupled to the drift control region; and
a multi-level capacitive structure in the semiconductor body that is self-adjusted to the drift control region dielectric and forms part of at least one of the gate structure and the capacitive element.

17. The transistor device of claim 16, wherein the multi-level capacitive structure comprises:
a 1st level capacitive structure in the semiconductor body, the 1st level capacitive structure comprising a first trench, a first dielectric layer on sidewalls and a bottom of the first trench and a first electrode layer on the first dielectric layer; and
at least one 2nd level capacitive structure in the semiconductor body, the at least one 2nd level capacitive structure comprising a second trench adjusted to one sidewall of the first trench, a second dielectric layer on sidewalls and a bottom of the second trench and a second electrode layer on the second dielectric layer.

18. The transistor device of claim 17, wherein the capacitive element comprises the at least one 2nd level capacitive structure.

19. The transistor device of claim 18, wherein the gate structure comprises the 1st level capacitive structure.

20. The transistor device of claim 17, wherein the multi-level capacitive structure further comprises at least one 3rd level capacitive structure, the at least one 3rd level capacitive structure comprising a third trench adjusted to one sidewall of the second trench, a third dielectric layer on sidewalls and a bottom of the third trench and a third electrode layer arranged on the third dielectric layer.

21. The transistor device of claim 20, wherein the capacitive element comprises the at least one 3rd level capacitive structure.

22. The transistor device of claim 21, wherein the gate structure comprises the at least one 1st level capacitive structure.

23. The transistor device of claim 21, wherein the multi-level capacitive structure comprises two 2nd level capacitive structures, wherein the at least one 3rd level capacitive structure is adjusted to the trench of a first one of the 2nd level capacitive structures, and wherein the gate structure comprises a second one of the 2nd level capacitive structures.

24. The transistor device of claim 23, wherein the second electrode layer of the first one of the 2nd level capacitive structures is connected to the drift control region.

25. The transistor device of claim 23, wherein the first electrode layer of the 1st level capacitive structures is connected to the drift control region.
